(19) United States
(12) Patent Application Publication
(10) Pub. No.: US 2017/0022610 A1
(43) Pub. Date: Jan. 26, 2017

(54) WAFER PROCESSING APPARATUS HAVING GAS INJECTOR

(71) Applicant: Samsung Electronics Co., Ltd., Suwon-si (KR)

(72) Inventors: Eun-Sung Seo, Hwaseong-si (KR); Yong-Kwon Kim, Hwaseong-si (KR); Young-Jin Noh, Suwon-si (KR); Young-Chang Song, Hwaseong-si (KR); Jae-Myung Choe, Seoul (KR); Ji-Hoon Choi, Seongnam-si (KR); Sang-Cheol HA, Suwon-si (KR)

(21) Appl. No.: 15/066,318

(22) Filed: Mar. 10, 2016

(30) Foreign Application Priority Data
Jul. 23, 2015 (KR) 10-2015-0104090

(51) Int. Cl. C23C 16/455; C23C 16/44; C23C 16/24

(52) U.S. Cl. CPC C23C 16/45544; C23C 16/45563; C23C 16/24; C23C 16/4412

(57) ABSTRACT

A wafer processing apparatus may include a reaction tube extending in a vertical direction and defining a process chamber for receiving a boat that holds a plurality of wafers. A gas injector may be configured to supply a reaction gas into the process chamber and may include a gas distributor extending in the vertical direction in the reaction tube. The gas injector may have a plurality of ejection holes for spraying the reaction gas. An inner diameter of the gas distributor may be at least 10 mm, and a sectional area ratio of the total sectional area of the ejection holes to a sectional area of the gas distributor is about 0.3 or less.

### PRIORITY STATEMENT

This application claims priority under 35 U.S.C. §119 to Korean Patent Application No. 10-2015-0104090, filed on Jul. 23, 2015 in the Korean Intellectual Property Office (KIPO), the contents of which are herein incorporated by reference in their entirety.

### BACKGROUND

1. Field

Example embodiments relate to a wafer processing apparatus having a gas injector. More particularly, example embodiments relate to a wafer processing apparatus for processing a plurality of wafers.

2. Description of the Related Art

A plurality of vertically stacked wafers may be loaded into a batch reactor and then an atomic layer deposition (ALD) process may be performed to form a layer on the wafers. For example, a blocking layer, a charge storage layer, and a tunnel insulation layer of a cell transistor of a vertical memory device such as vertical NAND (VNAND) may be formed in a batch reactor using an ADL process.

A conventional gas injector may include a cylindrical gas nozzle that extends in a vertical direction within a batch type reaction chamber. The cylindrical gas nozzle may spray a process gas on the vertically stacked wafers. However, an inner pressure and an ejection velocity may decrease with a height in the gas injector. A pressure difference and an ejection velocity difference between upper and lower portions of the gas injector may increase the difference in deposition layers between wafers in the chamber, leading to inconsistent performance and reduced reliability. That is, because of the pressure and ejection velocity variation within the chamber, wafer-to-wafer (WTW) layer thickness distribution may be deteriorated (for example, increased, when a uniform distribution may be desired).

### SUMMARY

Example embodiments in accordance with principles of inventive concepts provide a wafer processing apparatus configured to form uniform thin layers on wafers in a batch type reaction tube.

In example embodiments in accordance with principles of inventive concepts, a wafer processing apparatus includes a reaction tube extending in a vertical direction and defining a process chamber for receiving a boat that holds a plurality of wafers, and a gas injector configured to supply a reaction gas into the process chamber and comprising a gas distributor extending in the vertical direction in the reaction tube and having a plurality of ejection holes for spraying the reaction gas. An inner diameter of the gas distributor is at least 10 mm, and a sectional area ratio of the total sectional area of the ejection holes to a sectional area of the gas distributor is about 0.3 or less.

In example embodiments in accordance with principles of inventive concepts, the inner diameter of the gas distributor may be within a range of about 10.5 mm to about 15.5 mm.

In example embodiments in accordance with principles of inventive concepts, a ratio of a height to an inner diameter of the reaction tube may be about 2:1 or less.

In example embodiments in accordance with principles of inventive concepts, a diameter of the ejection hole may be about 1 mm.

In example embodiments in accordance with principles of inventive concepts, the total number of the ejection holes may be 20 to 40.

In example embodiments in accordance with principles of inventive concepts, a lower end of the reaction tube may be an open end.

In example embodiments in accordance with principles of inventive concepts, the gas injector may supply a silicon precursor gas through the ejection holes to perform an atomic deposition layer process on the wafers, and a pressure of the reaction chamber may be maintained to about 50 Pa or less.

In example embodiments in accordance with principles of inventive concepts, the reaction tube may include a boat receiving portion having a first radius from the center of the reaction tube and surrounding the boat, an injector receiving portion having a second radius greater than the first radius and receiving the gas injector, and an exhaust guide receiving portion having a third radius greater than the first radius and opposite to the injector receiving portion.

In example embodiments in accordance with principles of inventive concepts, the injector receiving portion may have a first central angle at the center of the reaction tube and the exhaust guide receiving portion may have a second central angle greater than the first central angle at the center of the reaction tube.

In example embodiments in accordance with principles of inventive concepts, the wafer processing apparatus may further include an exhaust guide extending in the vertical direction in the exhaust guide receiving portion and configured to collect and exhaust a gas which is ejected from the gas distributor and flows through the boat.

In example embodiments in accordance with principles of inventive concepts, the exhaust guide may include an exhaust slit formed in an inner portion of the exhaust guide along the extending direction of the reaction tube and into which the reaction gas flows, and an exhaust hole formed in a lower outer portion of the exhaust guide and out of which the reaction gas flows.

In example embodiments in accordance with principles of inventive concepts, the gas injector may further include a gas introduction tube connected to a lower portion of the gas distributor and configured to introduce the reaction gas into the reaction tube from a gas supply source.

In example embodiments in accordance with principles of inventive concepts, the wafer processing apparatus may further include an exhaust portion configured to exhaust gas from the reaction chamber.

In example embodiments in accordance with principles of inventive concepts, the boat may be supported rotatably in the reaction tube.

In example embodiments in accordance with principles of inventive concepts, the wafer processing apparatus may further include at least one gas nozzle for supplying a reaction gas, a carrier gas, a cleaning gas or a purge gas into the reaction chamber.

In example embodiments in accordance with principles of inventive concepts, a wafer processing apparatus includes a reaction tube extending in a vertical direction and defining a process chamber, a boat configured to be loaded into the reaction tube and configured to hold a plurality of wafers, and a gas injector configured to supply a reaction gas into the process chamber and comprising a gas distributor extending in the vertical direction in the reaction tube and having a plurality of ejection holes for spraying the reaction gas. An inner diameter of the gas distributor is at least 10 mm, and a sectional area ratio of the total sectional area of the ejection holes to a sectional area of the gas distributor is about 0.3 or less.

In example embodiments in accordance with principles of inventive concepts, the inner diameter of the gas distributor may be within a range of about 10.5 mm to about 15.5 mm.

In example embodiments in accordance with principles of inventive concepts, the reaction tube may include a boat receiving portion having a first radius from the center of the reaction tube and surrounding the boat, an injector receiving portion having a second radius greater than the first radius and receiving the gas injector, and an exhaust guide receiving portion having a third radius greater than the first radius and opposite to the injector receiving portion.

In example embodiments in accordance with principles of inventive concepts, the wafer processing apparatus may further include an exhaust guide extending in the vertical direction in the exhaust guide receiving portion and configured to collect, and exhaust a gas which is ejected from the gas distributor and flows through the boat.

In example embodiments in accordance with principles of inventive concepts, the exhaust guide may include an exhaust slit formed in an inner portion of the exhaust guide along the extending direction of the reaction tube and into which the reaction gas flows, and an exhaust hole formed in a lower outer portion of the exhaust guide and out of which the reaction gas flows.

In example embodiments in accordance with principles of inventive concepts, a wafer processing apparatus may include a gas injector having a gas distributor which extends in the vertical direction in the reaction tube and has a plurality of ejection holes for spraying the reaction gas. The wafer processing apparatus may be a compact batch reactor with an aspect ratio (the height to the inner diameter of the reaction tube) of about 2:1 or less. The inner diameter of the gas distributor may be at least 10 mm, and a ratio (sectional area ratio) of the total sectional area of the ejection holes to the sectional area of the gas distributor to may be about 0.3 or less.

In example embodiments in accordance with principles of inventive concepts, when the inner diameter of the gas distributor is about 10 mm or more (when the sectional area ratio is about 0.3 or less), wafer-to-wafer (WTW) thickness uniformity may be improved, to thereby form uniform thin layers on the wafers in the reaction tube.

In example embodiments in accordance with principles of inventive concepts, the reaction tube may include the boat receiving portion surrounding the most of the outer circumference surface of the boat, the injector receiving portion receiving the gas injector, and the exhaust guide receiving portion receiving the exhaust guide.

In example embodiments in accordance with principles of inventive concepts, in a state where a spacing between the boat and the boat receiving portion is chosen to be minimized, the injector receiving portion and the exhaust guide receiving portion may be provided to make an inflow/outflow of the reaction gas balanced and uniform across the height of the reaction tube, thereby improving thickness distribution within wafer and across the wafers stacked in the boat.

In example embodiments in accordance with principles of inventive concepts, a batch reactor for atomic layer deposition includes, a reaction tube extending in a vertical direction and defining a process chamber, the reaction tube having a ratio of height to diameter of about two-to-one or less; and a cylindrical gas nozzle including ejection holes to spray reaction gas extending in a vertical direction in the reaction tube.

In example embodiments in accordance with principles of inventive concepts, a batch reactor for atomic layer deposition includes, a nozzle having an inner diameter of at least 10 mm.

In example embodiments in accordance with principles of inventive concepts, a batch reactor for atomic layer deposition includes, a gas nozzle with the total area of the hole openings consume about thirty percent or less of the total vertical area of the gas nozzle.

In example embodiments in accordance with principles of inventive concepts, a batch reactor for atomic layer deposition includes between twenty and forty holes in the gas nozzle.

In example embodiments in accordance with principles of inventive concepts, a batch reactor for atomic layer deposition includes holes having a diameter of about 1 mm.

### BRIEF DESCRIPTION OF THE DRAWINGS

Example embodiments will be more clearly understood from the following detailed description taken in conjunction with the accompanying drawings. FIGS. 1 to 23 represent non-limiting, example embodiments as described herein.

FIG. 1 is a cross-sectional view illustrating a wafer processing apparatus in accordance with some example embodiments.

FIG. 2 is a perspective view illustrating a reaction tube of the wafer processing apparatus in FIG. 1.

FIG. 3 is a cross-sectional view taken along the line A-A′ in FIG. 2.

FIG. 4 is a cross-sectional view illustrating a gas injector and an exhaust guide in the reaction tube of the wafer processing apparatus in FIG. 1.

FIG. 5 is a cross-sectional view illustrating the gas injector of the wafer processing apparatus in FIG. 1.

FIG. 6 is a perspective view illustrating the exhaust guide of the wafer processing apparatus in FIG. 1.

FIG. 7 is a front view illustrating the exhaust guide in FIG. 6.

FIG. 8 is a rear view illustrating the exhaust guide in FIG. 6.

FIG. 9 is a cross-sectional view taken along the line B-B′ line in FIG. 6.

FIG. 10 is graphs illustrating a gas ejection velocity according to a height in a boat.

FIG. 11 is graphs illustrating a gas concentration according to a height in a boat.

FIG. 12 is graphs illustrating concentration deviation across wafers according to a diameter of a gas distributor.

FIG. 13 is a flow chart illustrating a method of processing a wafer in accordance with example embodiments.

FIGS. 14 to 23 are vertical cross-sectional views illustrating a method of manufacturing a vertical memory device in accordance with example embodiments.

### DETAILED DESCRIPTION OF EXAMPLE EMBODIMENTS

Various example embodiments will be described more fully hereinafter with reference to the accompanying drawings, in which example embodiments in accordance with principles of inventive concepts are shown. Inventive concepts may, however, be embodied in many different forms and should not be construed as limited to example embodiments set forth herein. Rather, these example embodiments are provided so that this disclosure will be thorough and complete, and will fully convey the scope of inventive concepts to those skilled in the art. In the drawings, the sizes and relative sizes of components or elements may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element or layer is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of inventive concepts. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, example embodiments will be explained in detail with reference to the accompanying drawings.

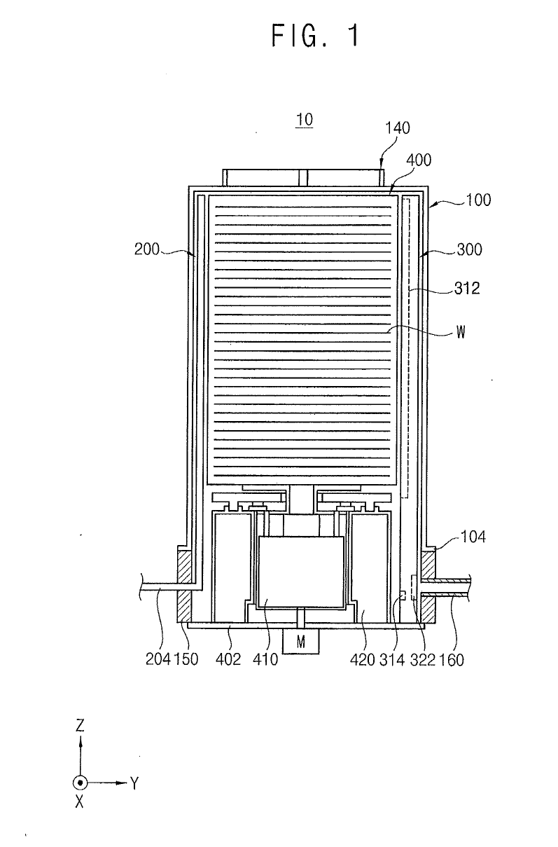

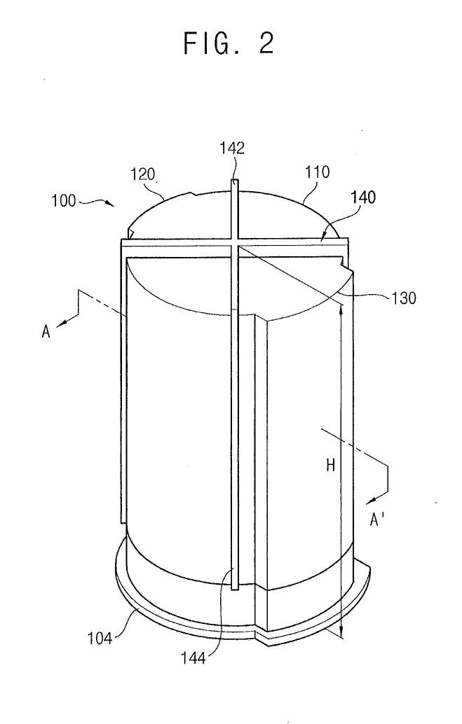

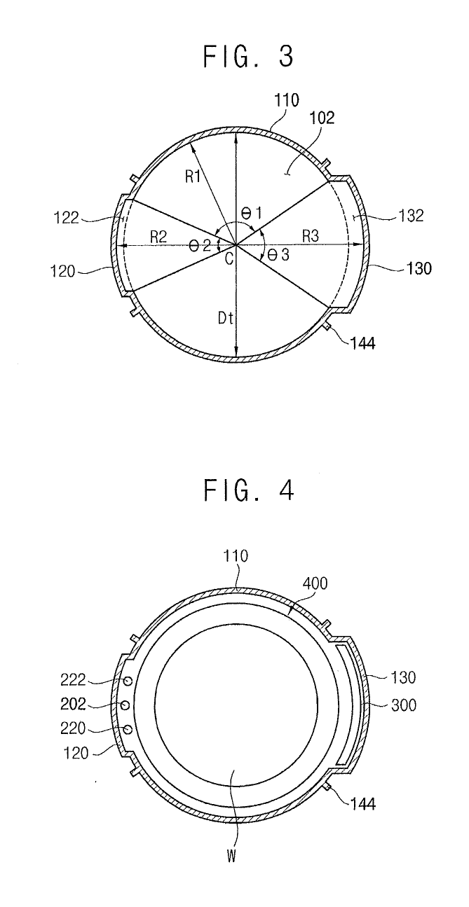

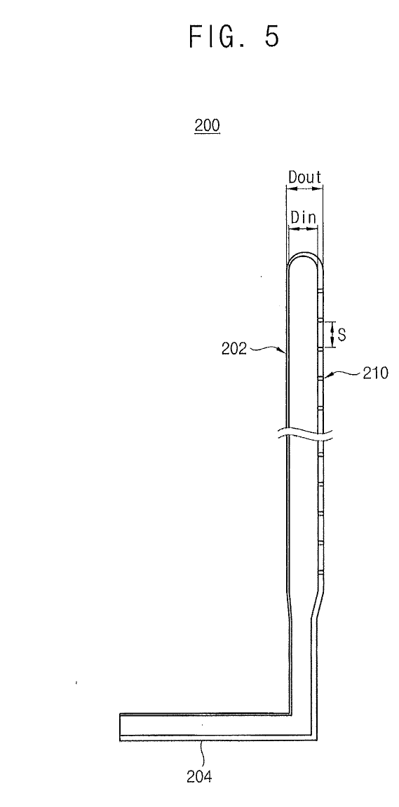

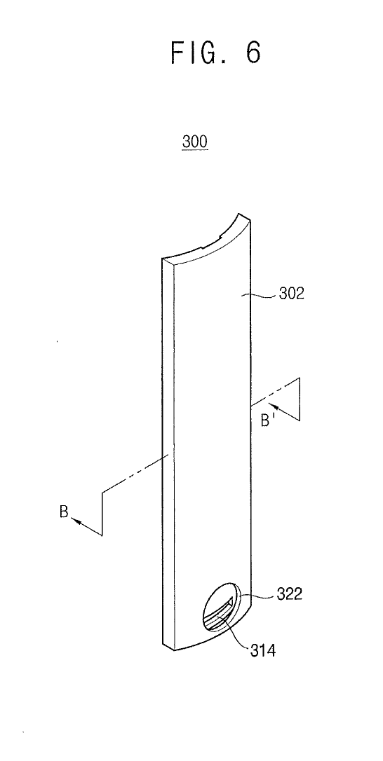

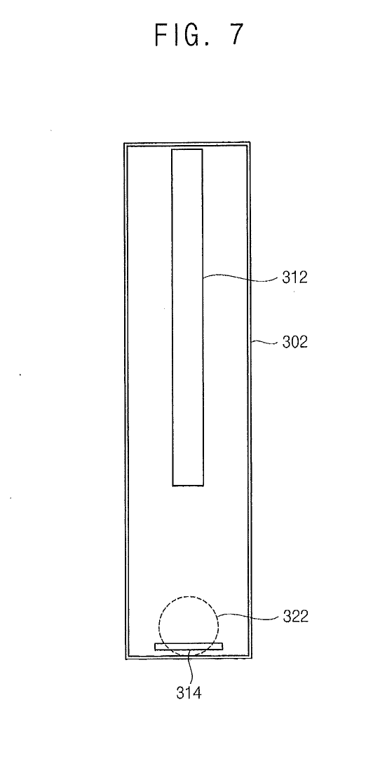

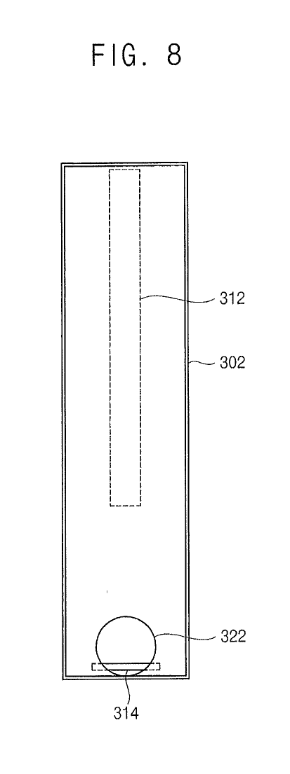

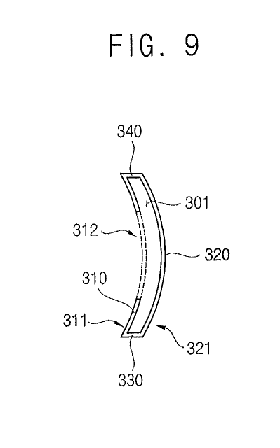

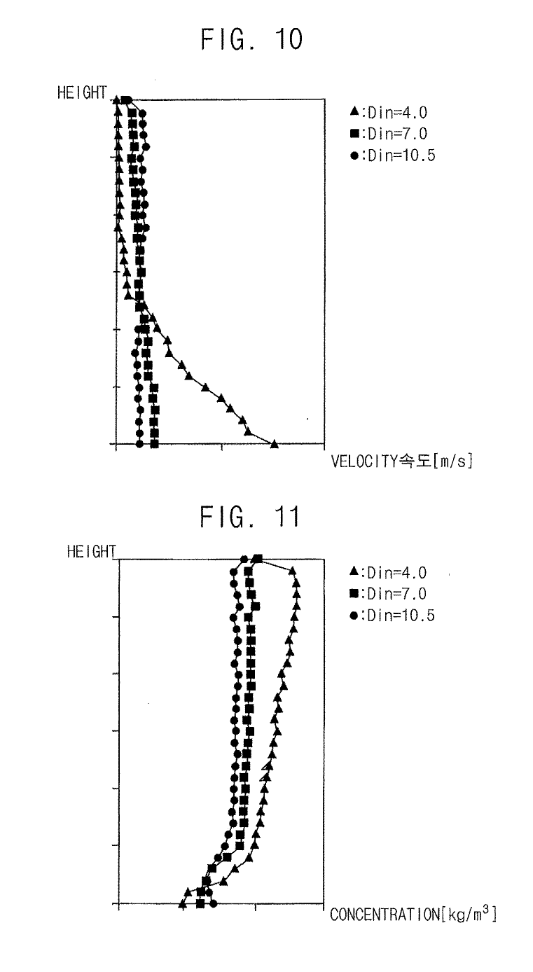

FIG. 1 is a cross-sectional view illustrating an example embodiment of a wafer processing apparatus in accordance with inventive concepts. FIG. 2 is a perspective view illustrating a reaction tube of the wafer processing apparatus in FIG. 1. FIG. 3 is a cross-sectional view taken along the line A-A′ in FIG. 2. FIG. 4 is a cross-sectional view illustrating a gas injector and an exhaust guide in the reaction tube of the wafer processing apparatus in FIG. 1. FIG. 5 is a cross-sectional view illustrating the gas injector of the wafer processing apparatus in FIG. 1. FIG. 6 is a perspective view illustrating the exhaust guide of the wafer processing apparatus in FIG. 1. FIG. 7 is a front view illustrating the exhaust guide in FIG. 6. FIG. 8 is a rear view illustrating the exhaust guide in FIG. 6. FIG. 9 is a cross-sectional view taken along the line B-B′ line in FIG. 6.

Referring to FIGS. 1 to 6, a wafer processing apparatus 10 in accordance with principles of inventive concepts may include a reaction tube 100 extending in a vertical direction and providing a space within which a plurality of wafers W may be processed, and a gas injector 200 configured to spray a reaction gas on the wafers W in the reaction tube 100. The wafer processing apparatus 10 may further include a boat 400 configured to be loaded into and unloaded from the reaction tube 100 and configured to support a plurality of the wafers W.

In example embodiments, the wafer processing apparatus 10 may include a vertical batch reactor. The reaction tube 100 may extend in the vertical direction (Z direction) to define a reaction chamber 102. The vertical batch reactor may receive the boat 400 that holds a plurality of the wafers W therein. The batch reactor may have benefits for efficient heating and loading sequences.

A lower portion of the reaction tube 100 may include an open end, and an upper portion of the reaction tube 100 may include a closed end. The lower open end of the reaction tube 100 may have a flange 104 that protrudes in a radial direction. The flange 104 may be installed in a support 150. For example, the flange 104 of the reaction tube 100 may be connected to the support 150 by a sealing member such as O-ring to seal the reaction tube 100. Accordingly, the reaction tube 100 may extend in the vertical direction from the support 150. Additionally, in operation, the reaction chamber 102 may be maintained at a desired temperature (that may or may not be predetermined) by a temperature control system such as a heater (not shown) that surrounds the reaction tube 100.

In example embodiments, the reaction tube 100 may have a height (H) of about 700 mm or less. The reaction tube 100 may have an inner diameter (Dt) of about 350 mm or less. The reaction tube 100 may have an aspect ratio (height to width ratio) of about 2:1 or less. In such example embodiments, the height (H) of the reaction tube 100 may be about 615 mm, and the inner diameter (Dt) of the reaction tube 100 may be about 334 mm. The reaction tube 100 may include quartz, for example.

As illustrated in FIGS. 2 to 4, in example embodiments, the reaction tube 100 may include a boat receiving portion 110 surrounding the boat 400, an injector receiving portion 120 receiving the gas injector 200, and an exhaust guide receiving portion 130 opposite to the injector receiving portion 120.

The boat receiving portion 110, the injector receiving portion 120 and the exhaust guide receiving portion 130 may have an arc shape to form a predetermined central angle at the center C of the reaction tube 100. The boat receiving portion 110 may have a first radius R1 from the center C of the reaction tube 100. The boat receiving portion 110 may have a first central angle θ1 at the center C of the reaction tube 100. The injector receiving portion 120 may have a second radius R2 greater than the first radius R1 from the center C of the reaction tube 100. The injector receiving portion 120 may have a second central angle θ2 at the center C of the reaction tube 100. The exhaust guide receiving portion 130 may have a third radius R3 greater than the first radius R1 from the center C of the reaction tube 100. The exhaust guide receiving portion 130 may have a third central angle θ3 at the center C of the reaction tube 100.

The second radius R2 and the third radius R3 may be greater than the first radius R1. The third radius R3 may be greater than the second radius R2. A spacing distance between an outer circumference surface of the boat 400 and an inner surface of the boat receiving portion 110 may be less than spacing distances between an outer circumference surface of the boat 400 and inner surfaces of the injector receiving portion 120 and the exhaust guide receiving portion 130. Accordingly, the boat receiving portion 110 may be positioned closest to the boat 400. In this example embodiment, the first radius R1 may be about 167 mm, the second radius R2 may be about 190 mm, and the third radius R3 may be about 204 mm. A diameter of the boat 400 may be about 160.5 mm.

In example embodiments in accordance with principles of inventive concepts; the first central angle θ1 may be within a range of about 105 degrees to about 135 degrees; the second central angle θ2 may be within a range of about 30 degrees to about 60 degrees; and the third central angle θ3 may be within a range of about 60 degrees to about 90 degrees.

The boat receiving portion 110 may be positioned closest to the boat 400 to surround most of the outer circumference surface of the boat 400. The injector receiving portion 120 may have a radius greater than the radius of the boat receiving portion 110 to include a first receiving recess 122. The first receiving recess 122 may extend in the vertical direction. A gas distributor 202 of the gas injector 200 may be disposed in the first receiving recess 122. The exhaust guide receiving portion 130 may have a radius greater than the radius of the boat receiving portion 110 to include a second receiving recess 132. The second receiving recess 132 may extend in the vertical direction. An exhaust guide 300 may be received in the second receiving recess 132.

The reaction tube 100 may further include a reinforcing rib 140. The reinforcing rib 140 may be provided in an outer surface of the reaction tube 100 to reinforce strength of the reaction tube 100. The reinforcing rib 140 may include at least two first extending portions 142 extending on an upper surface of the upper end portion of the reaction tube 100 to cross each other and at least four second extending portions 144 extending on an outer side surface of the reaction tube 100.

In example embodiments, the reaction chamber 102 may receive the boat 400 that holds a plurality of the wafers W that are supported therein to be spaced apart in the vertical direction. The boat 400 may be supported on a door plate 402, which may move upward and downward to load and unload the boat 400 into and from the reaction tube 100. A boat cap 410 may be disposed in a lower portion of the boat 400 to support the boat 400 and to serve as a heat dissipation plate. In example embodiments in accordance with principles of inventive concepts, at least 20 to 40 wafers W may be stacked in the boat 400.

The door plate 402 may be positioned under the reaction tube 100 to seal the reaction tube 100. The door plate 402 may be combined with the support 150 under the reaction tube 100 by a sealing member such as O-ring to seal the reaction tube 100, for example.

A cap plate 420 may be positioned on the door plate 402 and surround the boat cap 410 in the lower portion of the boat 400. The cap plate 420 may be interposed between the door plate 402 and the lower portion of the boat 400 to receive the boat cap 410. The cap plate 420 may be arranged to face an inner surface of the support 150.

Accordingly, the cap plate 420 may prevent process gases or by-products in the reaction tube 100 from flowing into a space between the support 150 and the cap plate 420.

A rotational shaft may extend from the lower portion of the boat 400 and may be connected to a motor M provided on an outer surface of the door plate. Accordingly, the boat 400 on the door plate 402 may be supported rotatably in the reaction tube 100. In operation, while the boat 400 is rotated at a desired speed (that may or may not be predetermined), reaction gases may be introduced on the wafers W to perform a deposition process.

As illustrated in FIGS. 4 and 5, in example embodiments, the gas injector 200 may be installed in the reaction tube 100 to supply a reaction gas onto the wafers W. The gas injector 200 may include ejection holes 210 for spraying, or injecting, the process gas. The process gas may be ejected toward the center of the reaction tube 100 in a horizontal plane (XY direction) parallel with principal surfaces of the wafers W.

In example embodiments in accordance with principles of inventive concepts, the gas injector 200 may include a gas introduction tube 204 for introducing the reaction gas into the reaction tube 100 from a gas supply source and a gas distributor 202 connected to the gas introduction tube 204. The gas distributor 202 may extend from the gas introduction tube 204 in the vertical direction within the reaction tube 100. The gas distributor 202 may have a plurality of the ejection holes 210 formed in an inner surface of the gas distributor 202 to be spaced apart from each other in the vertical direction and configured to spray the reaction gas. The gas injector 200 may include quartz, stainless steel, or a metal alloy, for example.

The gas introduction tube 204 may penetrate the support 150 under the reaction tube 100 to extend to the inside of the support 150, that is, a space between the support 150 and the cap plate 420. The gas introduction tube 204 may serve as an inlet through which the reaction gas is injected into the reaction chamber 102 from the gas supply source. The gas supply source may supply a source gas for an atomic layer deposition (ALD) process. In example embodiments in accordance with principles of inventive concepts, the gas supply source may supply the source gas for deposition of a silicon oxide layer, or a silicon nitride layer, for example. The source gas may include a silicon precursor gas such as hexachlorodisilane (HCDS).

The gas distributor 202 may extend in the vertical direction of the reaction tube 100 between the boat 400 and the reaction tube 100. The gas distributor 202 may extend in the vertical direction within the first receiving recess 122 of the injector receiving portion 120.

A plurality of the ejection holes 210 may be arranged to be spaced apart by a desired distance S (that may or may not be predetermined) from each other in the vertical direction. The ejection holes 210 may be formed to extend toward, or open in the direction of, the boat 400, and the ejection holes 210 may be spaced apart from each other from a lower end portion of the gas distributor 202 to an upper end portion of the gas distributor 202 such that the ejection holes may spray the process gas in horizontal directions parallel with the principal surfaces of the wafers W stacked in the boat 400. In example embodiments in accordance with principles of inventive concepts, the ejection holes may have circular, oval, or polygonal shapes, and a gas distributing path of the gas distributor may have a circular, oval, or polygonal sectional shape, for example.

In example embodiments, an inner diameter (Din) of the gas distributor 202 may be at least 10 mm. In particular, the inner diameter (Din) of the gas distributor 202 may be within a range of about 10.5 mm to about 15.5 mm. When the inner diameter (Din) of the gas distributor 202 is about 10.5 mm, a sectional area (A1) of the distributing path of the gas distributor 202 may be about 86.5 mm². When the inner diameter (Din) of the gas distributor 202 is about 15.5 mm, the sectional area (A1) of the gas distributor 202 may be about 188.6 mm². A diameter of the ejection hole 210 may be about 1 mm. The total number of the ejection holes 210 may be from 20 to 40. In such example embodiments, the total number of the ejection holes 210 may be 31, the total sectional area (A2) of the ejection holes 210 may be about 24.3 mm², the height (Hi) of the gas injector 200 may be about 633 mm, and the height (Hd) of the gas distributor 202 may be about 577 mm.

In example embodiments in accordance with principles of inventive concepts, the ratio (A2/A1) of the total sectional area (A2) of the ejection holes 210 to the sectional area (A1) of the gas distributor 202 may be about 0.3 or less. For example, the ratio (A2/A1) of the total sectional area (A2) of the ejection holes 210 to the sectional area (A1) of the gas distributor 202 may be within a range of about 0.13 to about 0.28.

In example embodiments in accordance with principles of inventive concepts, when the inner diameter (Din) of the gas distributor 202 is about 10 mm or more (when the sectional area ratio (A2/A1) is about 0.3 or less), the distributions of the gas injection velocity and the gas concentration (gas flow amount) may be uniform, as desired, with the height of the gas injector 202. Accordingly, when the inner diameter (Din) of the gas distributor 202 is about 10 mm or more (when the sectional area ratio (A2/A1) is about 0.3 or less), wafer-to-wafer (WTW) thickness uniformity may be improved, to thereby form uniform thin layers on the wafers W in the reaction tube 100.

As described in greater detail later, as counter-examples, if the inner diameter (Din) of the gas distributor 202 were about 10 mm or less (when the sectional area ratio (A2/A1) is greater than about 0.3), distributions of a gas injection velocity and a gas concentration (gas flow amount) may be non-uniform with the height of the gas injector 202 and were the inner diameter (Din) of the gas distributor 202 about 15.5 mm or more (when the sectional area ratio (A2/A1) is less than about 0.13), positional interference between the gas distributor 202 and the outer circumference surface of the boat 400 may occur, both undesirable outcomes avoided by example embodiments in accordance with principles of inventive concepts.

In example embodiments, the wafer processing apparatus 10 may include at least one gas nozzle for supplying a reaction gas, a carrier gas, a cleaning gas or a purge gas into the reaction chamber 102. For example, the wafer processing apparatus 10 may include a first gas nozzle 220 and a second gas nozzle 222. The first and second gas nozzles 220 and 222 may extend in the vertical direction between the boat 400 and the reaction tube 100. The first and second gas nozzles 220 and 222 may extend within the first receiving recess 122 of the injector receiving portion 120. The gas injector 200, the first gas nozzle 220 and the second gas nozzle 222 may eject N₂ gas, HF gas, NF₃ gas, for example.

In example embodiments, the wafer processing apparatus 10 may include an exhaust portion which exhausts a gas from the reaction chamber 102.

The exhaust portion may include an exhaust port 160 that is connected to a space in the reaction tube 100. The exhaust port 160 may be formed to penetrate through the support 150 in which the flange 104 of the reaction tube 100 is installed. Accordingly, the gas in the reaction chamber 102 may flow out of the reaction tube 100 via the exhaust port 160.

Referring to FIGS. 4 and 6 to 9, the wafer processing apparatus 10 may further include the exhaust guide 300 received in the exhaust guide receiving portion 130. The exhaust guide 300 may include a guide body 302 extending in the vertical direction within the second receiving recess 132 of the exhaust guide receiving portion 130 to provide a path through which a gas flows. The guide body 302 of the exhaust guide 300 may provide an exhaust path 301 for collecting and exhausting a gas which flows from the gas distributor 202 via the boat 400 and enters into the guide body 302. In example embodiments, the exhaust guide 300 may include quartz, for example.

The guide body 302 of the exhaust guide 300 may include an arc-shaped inner portion 310, an arc-shaped outer portion 320, and first and second side portions 330 and 340 connecting the inner portion 310 and the outer portion 320. The inner portion 310 and the outer portion 320 may form the exhausting, or exhaust path 301, for the gas therebetween.

The inner portion 310 may be spaced apart from the outer circumference surface of the boat 400, and the outer portion 320 may be spaced apart from the inner circumference surface of the reaction tube 100. An inner surface 311 of the inner portion 310 may be arranged to face the boat 400, and an outer surface 321 of the outer portion 320 may be arranged to face the inner surface of the reaction tube 100.

The exhaust guide 300 may include an exhaust slit 312 and an exhaust hole 322. The exhaust slit 312 may be formed in the inner portion 310 along the extending direction of the reaction tube 100. A reaction gas may flow into the exhaust body 302 through the exhaust slit 312. The exhaust hole 322 may be formed in a lower portion of the outer portion 320. The reaction gas may flow out of the exhaust body 302 through the exhaust hole 322. The exhaust guide 300 may further include an exhaust slit hole 314. The exhaust slit hole 314 may be formed in a lower portion of the inner portion 310. A gas in the lower portion of the reaction tube 100 within the support 150 may be exhausted through the exhaust slit hole 314.

The exhaust slit 312 may be formed to extend in the vertical direction corresponding to heights of the wafers W stacked in the boat 400. The exhaust hole 322 may be formed at a position corresponding to the exhaust port 160 which penetrates through the support 150. The exhaust slit hole 314 may be formed at a position corresponding to the lower portion of the boat 400 within the support 150.

In example embodiments in accordance with principles of inventive concepts, in operation a reaction gas may be ejected toward the wafers W by the gas distributor 202, and then, the reaction gas may flow into the guide body 302 through the exhaust slit 312 and flow out of the guide body 302 through the exhaust hole 322. The gas flowing out of the exhaust guide 300 may be exhausted via the exhaust port 160.

In example embodiments, the wafer processing apparatus 10 may further include a pressure control unit for controlling a pressure in the reaction tube 100. The pressure control unit may include a pump (not shown) which is connected to the exhaust port 160 to adjust the pressure of the reaction tube 100. For example, the pressure control unit may maintain the pressure of the reaction tube 102 to about 50 Pa or less.

As mentioned above, the wafer processing apparatus 10 may include gas injector 200 including gas distributor 202 in which a plurality of the ejection holes 210 is formed to spray a reaction gas in the reaction tube 100. In example embodiments in accordance with principles of inventive concepts, wafer processing apparatus 10 may be a compact batch reactor with an aspect ratio (the height (H) to the inner diameter (Dt) of the reaction tube 100) of about 2:1 or less. The inner diameter (Din) of the gas distributor 202 may be at least 10 mm, and a ratio of the total sectional area (A2) of the ejection holes 210 to the sectional area (A1) of the gas distributor 202 to may be about 0.3 or less.

In exemplary embodiments in accordance with principles of inventive concepts, when the inner diameter (Din) of the gas distributor 202 is about 10 mm or more (when the sectional area ratio (A2/A1) is about 0.3 or less), wafer-to-wafer (WTW) thickness uniformity may be improved, to thereby form uniform thin layers on the wafers W in the reaction tube 100. Additionally, the reaction tube 100 may include the boat receiving portion 110 surrounding the most of the outer circumference surface of the boat 400, the injector receiving portion 120 receiving the gas injector 200, and the exhaust guide receiving portion 130 receiving the exhaust guide 300. Accordingly, exemplary embodiments in which the spacing between the boat 400 and the boat receiving portion 110 is chosen to be minimized, the injector receiving portion 120 and the exhaust guide receiving portion 130 may be provided to make an inflow/outflow of the reaction gas balanced and uniform across the height of the reaction tube 100, thereby improving thickness distribution within wafer and across the wafers stacked in the boat 400.

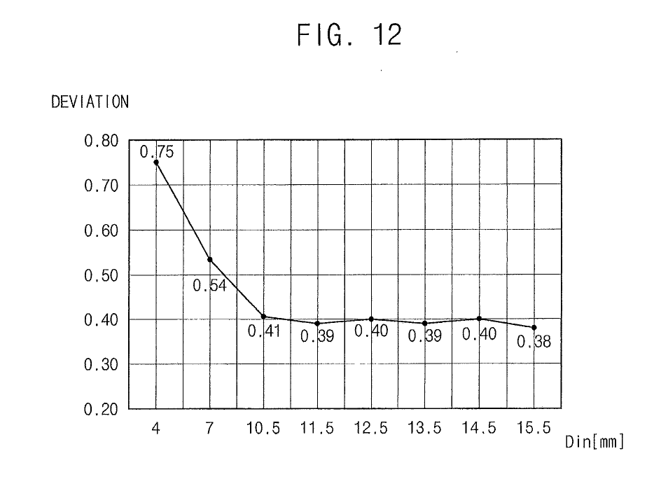

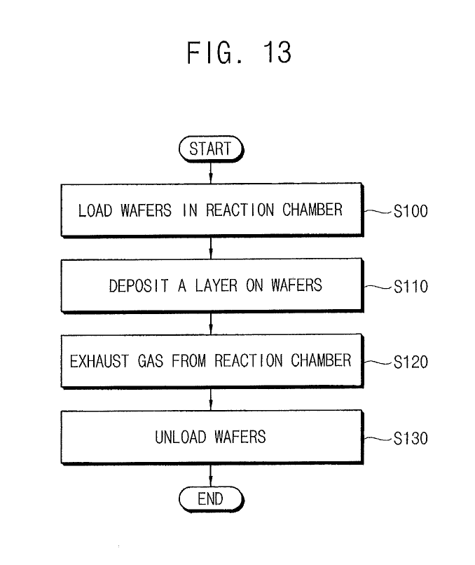

FIG. 10 is graphs illustrating gas ejection velocity according to a height in a boat. FIG. 11 is a graph illustrating a gas concentration according to a height in a boat. FIG. 12 is a graph illustrating concentration deviation across wafers according to a diameter of a gas distributor.

Referring to FIGS. 10 to 12, when a pressure of the reaction chamber 102 is 50 Pa and a ratio of HCD gas and N₂ gas introduced into the gas introduction tube 204 is 0.2:1, a gas ejection velocity and a gas concentration according to a height of the boat 400 and concentration deviation across wafers with respect to the inner diameter (Din) of the gas distributor 104 were measured.

As illustrated in FIG. 10, when the inner diameter (Din) of the gas distributor 202 is about 4 mm (when the sectional area ratio (A2/A1) is about 1.93), a gas ejection velocity was decreased dramatically with a height in the gas distributor 202. When the inner diameter (Din) of the gas distributor 202 is about 7 mm (when the sectional area ratio (A2/A1) is about 0.63), the gas ejection velocity was decreased gradually with a height in the gas distributor 202. In contrast, when the inner diameter (Din) of the gas distributor 202 is about 10.5 mm (when the sectional area ratio (A2/A1) is about 0.28), the gas ejection velocity distribution according to the height in the gas distributor 202 was uniform. When the inner diameter (Din) of the gas distributor 202 is within a range of about 10.5 mm to 15.5 mm, the gas ejection velocity distribution according to the height in the gas distributor 202 was uniform. When the inner diameter (Din) of the gas distributor 202 is about 10 mm or more (when the sectional area ratio (A2/A1) is about 0.3 or less), the gas ejection velocity distribution according to the height in the gas distributor 202 was uniform.

As illustrated in FIGS. 11 and 12, when the inner diameter (Din) of the gas distributor 202 is about 10.5 mm or more (10.5 mm, 11.5 mm, 12.5 mm, 13.5 mm, 14.5 mm, 15.5 mm), the gas concentration distribution according to the height in the gas distributor 202 is uniform. When the inner diameter (Din) of the gas distributor 202 is about 10 mm or more (when the sectional area ratio (A2/A1) is about 0.3 or less), the gas concentration distribution according to the height in the gas distributor 202 is uniform. The concentration deviation may be defined as the difference of the minimum value from the maximum value divided by the mean value.

In exemplary embodiments in accordance with principles of inventive concepts, when the inner diameter (Din) of the gas distributor 202 is about 10 mm or more (when the sectional area ratio (A2/A1) is about 0.3 or less), the gas ejection velocity difference and the concentration difference between the upper and lower portions of the gas distributor may be reduced, thereby improving the process uniformity. As a result, a manufacturing process of VNAND according to example embodiments, the thickness distribution of the deposition layer may be improved from 3.0 Å to 1.3 Å.

Hereinafter, an example method of processing a plurality of wafers using the wafer processing apparatus in FIG. 1, and a method of manufacturing a semiconductor device using the same in accordance with principles of inventive concepts will be explained.

FIG. 13 is a flow chart illustrating an example method of processing a wafer in accordance with principles of inventive concepts. The method may be used to form a silicon oxide layer or a silicon nitride layer on a wafer in an atomic layer deposition process. However, inventive concepts are not limited thereto.

Referring to FIGS. 1, 4, and 13, a plurality of wafers W may be loaded into a reaction chamber 102 of a wafer processing apparatus 10 (S100).

A reaction tube 100 of the wafer processing apparatus 10 may extend in a vertical direction to define the reaction chamber 102. A stand-by chamber (not shown) may be disposed under the reaction chamber 102 and may be arranged in the vertical direction. After the wafers W are transferred into a boat 400, the boat 400 may be raised and loaded into the reaction chamber 102 by a driving unit (not shown).

Then, a reaction gas may be supplied toward the wafers W through ejection holes 210 of a gas injector 200, respectively, to deposit a layer on the wafers W (S110).

The gas distributor 202 of the gas injector 200 may extend in the vertical direction between the reaction tube 100 and the boat 400. The reaction gas may be ejected toward the center C of the reaction tube 100 via a plurality of the ejection holes 210 which are formed in an inner surface of the gas injector 200.

In example embodiments, the reaction gas may include a source gas for forming a blocking layer, a charge storage layer, and a tunnel insulation layer of a cell transistor of VNAND. The source gas may include a silicon precursor gas such as hexachlorodisilane (HCDS). Additionally, a pulse gas or a cleaning gas may be supplied into the reaction chamber 102. Accordingly, an ALD process may be performed to form an insulation layer such as silicon oxide or silicon nitride layer on each of the wafers W.

Then, a gas may be exhausted from the reaction chamber 102 (S120).

The gas in the reaction chamber 102 may be exhausted from the reaction tube 100 through an exhaust port 160 that is formed in a support 150.

After forming the layer having a desired thickness (that may or may not be predetermined) on the wafers W, the wafers W may be unloaded from the reaction chamber 102 (S130).

In example embodiments, after the deposition process including the steps S100, S110, S120, and S130 are completed, whether or not to perform a cleaning process in the reaction chamber 102 may be determined (S140) (not shown). When it is determined that the cleaning process is not required to be performed, the deposition process including the steps S100, S110, S120, and S130 may be performed again in the reaction tube 100.

Hereinafter, an example method of manufacturing a semiconductor device using the wafer processing method in accordance with principles of inventive concepts of FIG. 13 will be described.

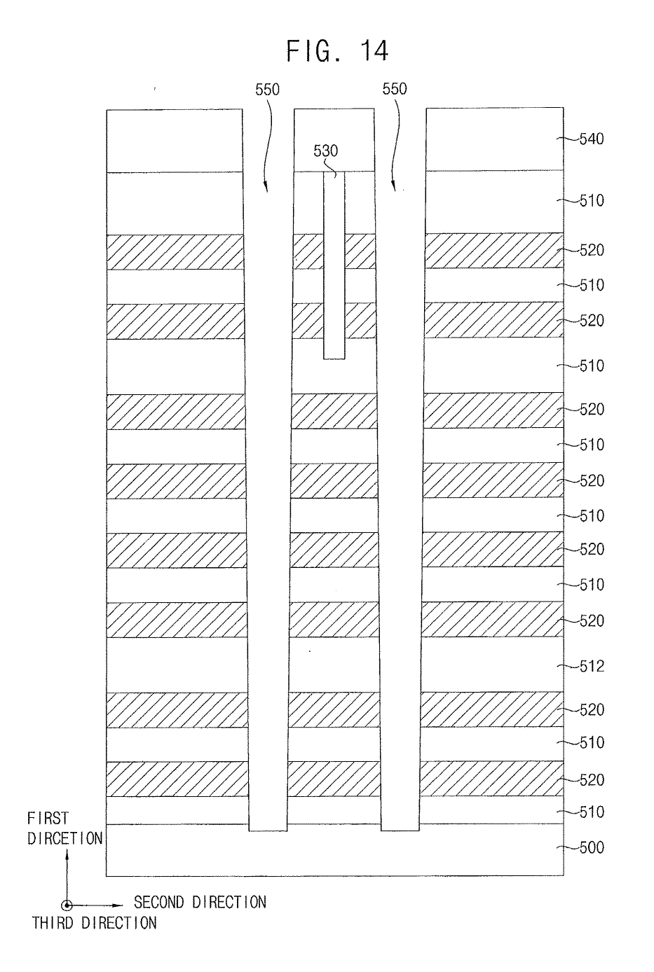

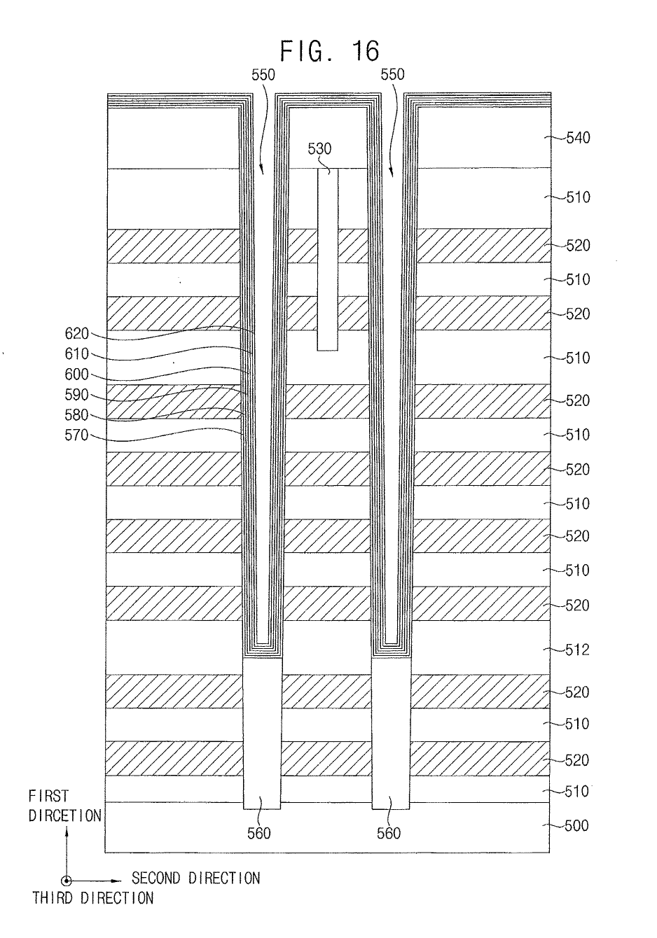

FIGS. 14 to 23 are vertical cross-sectional views illustrating a method of manufacturing a vertical memory device in accordance with example embodiments. In figures in this specification, a direction substantially perpendicular to a top surface of a substrate is referred to as a first direction, and two directions substantially parallel to the top surface of the substrate and substantially perpendicular to each other are referred to as a second direction and a third direction. Additionally, a direction indicated by an arrow in the figures and a reverse direction thereto are considered as the same direction. The definition of the direction mentioned above is identical in all figures.

Referring to FIG. 14, a first insulation layer 510 and a sacrificial layer 520 may be alternately and repeatedly formed on a substrate 500 and, thus, a plurality of first insulation layers 510 and a plurality of sacrificial layers 520 may be alternately formed on each other at a plurality of levels in the first direction, respectively. The substrate 500 may include a semiconductor material, for example, silicon and/or germanium.

In example embodiments, the first insulation layers 510 and the sacrificial layers 520 may be formed by, for example, a chemical vapor deposition (CVD) process, a plasma enhanced chemical vapor deposition (PECVD) process, an atomic layer deposition process (ALD) process, for example. A lowermost first insulation layer 510, which may be formed directly on a top surface of the substrate 500, may be formed by, for example, a thermal oxidation process.

In example embodiments, the first insulation layer 510 may be formed to include a silicon oxide, and the first sacrificial layer 520 may be formed to include, for example, a material with an etch selectivity to the first insulation layer 510 (for example, silicon nitride and/or silicon boron nitride).

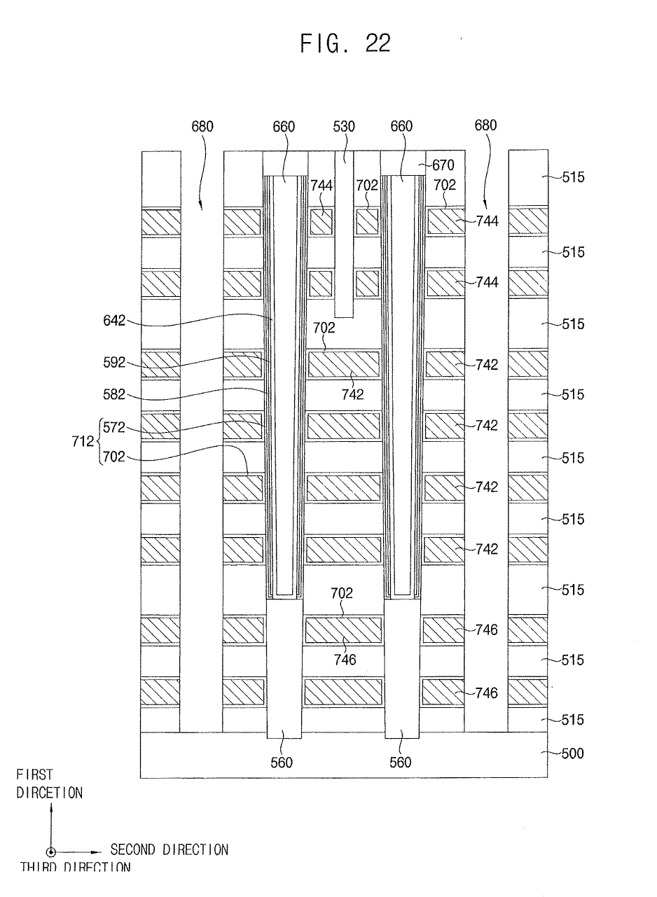

The number of the first insulation layers 510 and the number of the sacrificial layers 520 stacked on the substrate 500 may vary according to the desired stacked number of a ground select line (GSL) 746 (refer to FIG. 22), a word line 742 (refer to FIG. 22), and a string select line (SSL) 744 (refer to FIG. 22). According to example embodiments, each of the GSL 746 and the SSL 744 may be formed at 2 levels, and the word line 742 may be formed at 4 levels. Thus, the sacrificial layer 520 may be formed at 8 levels, and the first insulation layer 510 may be formed at 9 levels. However, example embodiments of the number of the first insulation layers 510 and the number of the sacrificial layers 520 stacked on the substrate 500 are not limited thereto and, for example, each of the GSL 746 and the SSL 744 may be formed at a single level, and the word line 742 may be formed at 2, 8, or 16 levels. In such embodiments, the sacrificial layers 520 may be formed at 4, 10, or 18 levels, and the first insulation layer 510 may be formed at 5, 11, or 19 levels.

Then, a trench may be formed partially through the first insulation layers 510 and the sacrificial layers 520, and a division layer pattern 530 filling the trench may be formed.

In example embodiments, the trench may be formed by a photolithography process. The trench may be formed through the sacrificial layers 520 in which the SSL 744 may be formed in a subsequent process and the first insulation layers 510 thereon, and further partially through the first insulation layer 510 therebeneath. In example embodiments, the trench may be formed to extend in the third direction.

A division layer may be formed on the first insulation layer 510 to sufficiently fill the trench, and may be planarized until a top surface of an uppermost first insulation layer 510 may be exposed to form the division layer pattern 530.

Then, a plurality of holes 550 may be formed through the first insulation layers 510 and the sacrificial layers 520 to expose a top surface of the substrate 500.

In example embodiments, after forming a hard mask 540 on the uppermost first insulation layer 510, the first insulation layers 510 and the sacrificial layers 520 may be dry etched using the hard mask 540 as an etch mask to form the holes 550. In this manner, the holes 550 may be formed to extend in the first direction. That is, each of the holes 550 may be formed to include a sidewall profile substantially perpendicular to the top surface of the substrate 500. Due to the characteristics of a dry etch process, the holes 550 may be of a width that becomes gradually smaller from a top portion to a bottom portion thereof and, thus, the sidewall profile may not be completely perpendicular to the top surface of the substrate 500, which is not shown.

In example embodiments, the hard mask 540 may be formed to include a material with an etch selectivity to silicon oxide and silicon nitride that may be included in the first insulation layers 510 and the sacrificial layers 520, respectively (for example, polysilicon or amorphous silicon by a CVD process, a PECVD process, an ALD process, and the like).

In example embodiments, a plurality of the holes 550, with openings in the first direction, may be arrayed in the second and third directions.

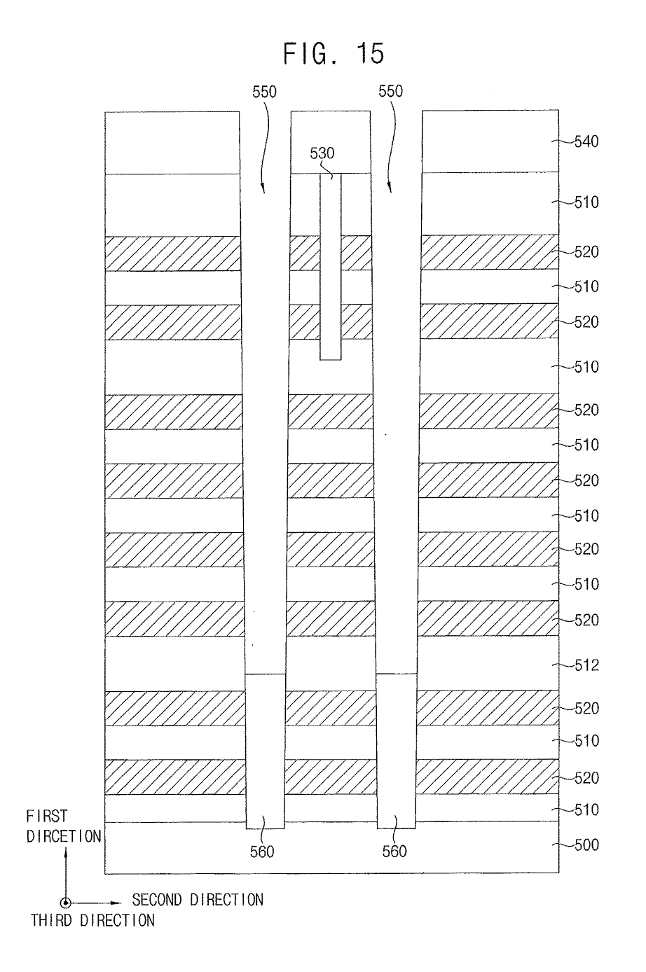

Referring to FIG. 15, a semiconductor pattern 560 may be formed to partially fill each of the holes 550.

In example embodiments, a selective epitaxial growth (SEG) process may be performed using the exposed top surface of the substrate 500 as a seed to form the semiconductor pattern 560 partially filling the holes 550. In this manner, the semiconductor pattern 560 may be formed to include single crystalline silicon or single crystalline germanium according to the material of the substrate 500 and, in some cases, impurities may be doped thereinto. Alternatively, an amorphous silicon layer may be formed to fill the holes 550, and a laser epitaxial growth (LEG) process or a solid phase epitaxy (SPE) process may be performed on the amorphous silicon layer to form the semiconductor pattern 560. In example embodiments, the semiconductor pattern 560 may be formed to have the top surface higher than that of the sacrificial layer 520 in which the GSL 746 may be formed subsequently.

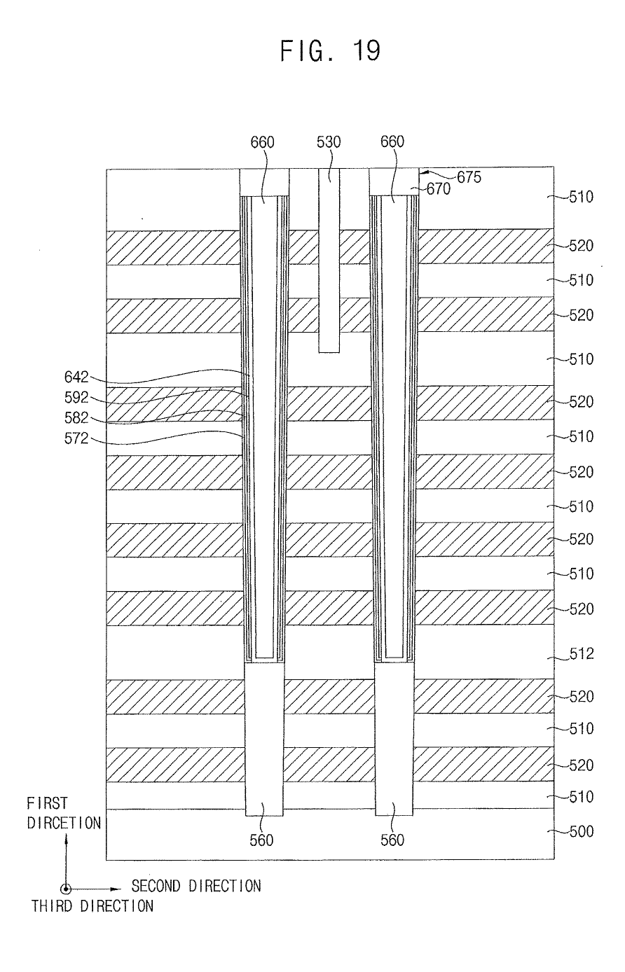

Referring to FIG. 19, a first blocking layer 570, a charge storage layer 580, a tunnel insulation layer 590, a first channel layer 600, an etch stop layer 610, and a spacer layer 620 may be sequentially formed on sidewalls of the holes 550, the top surface of the semiconductor pattern 560, and a top surface of the hard mask 540.

As illustrated in FIGS. 1 and 13, after the substrate 500 is loaded into the boat 400, the boat 400 may be raised and loaded into the reaction chamber 102 of the wafer processing apparatus 10. Then, a reaction gas for a deposition process may be supplied toward the substrate 500 through the ejection holes 210 of the gas distributor 202. Accordingly, ALD processes may be performed to form the first blocking layer 570, the charge storage layer 580, and the tunnel insulation layer 590 having uniform thicknesses in accordance with principles of inventive concepts may be sequentially formed on the substrate 500.

In example embodiments, the first blocking layer 570 may be formed to include an oxide (for example, silicon oxide), the charge storage layer 580 may be formed to include a nitride (for example, silicon nitride), and the tunnel insulation layer 590 may be formed to include an oxide (for example, silicon oxide).

In example embodiments, the first channel layer 600 may be formed to include doped or undoped polysilicon, or amorphous silicon. When the first channel layer 600 is formed to include amorphous silicon, an LEG process or an SPE process may be further performed so that the amorphous silicon layer may be changed to a crystalline silicon layer.

In example embodiments, the etch stop layer 610 may be formed to include substantially the same material as the first blocking layer 570 (for example, silicon oxide), and the spacer layer 620 may be formed to include substantially the same material as the charge storage layer 580 (for example, silicon nitride).

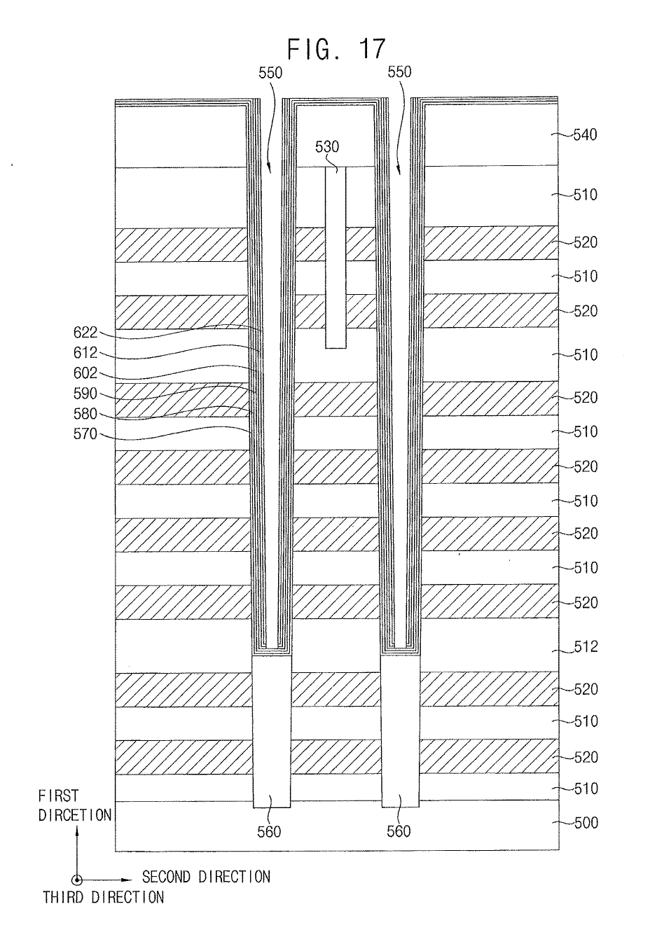

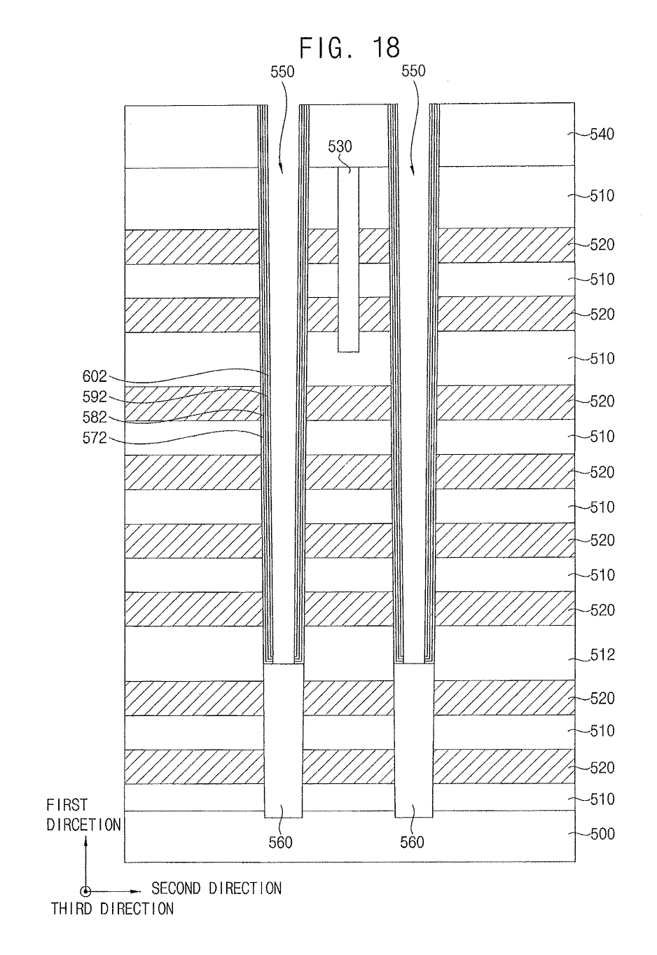

Referring to FIG. 17, a portion of the spacer layer 620 on the top surface of the semiconductor pattern 560 may be removed by etching the spacer layer 620 anisotropically to form a spacer 622 on the sidewall of each of the holes 550, and the etch stop layer 610 and the first channel layer 600 may be etched using the spacer 622 as an etch mask to form an etch stop layer pattern 612 and a first channel 602, respectively, exposing a portion of the tunnel insulation layer 590. In other words, portions of the etch stop layer 610 and the first channel layer 600 formed on the central top surface of the semiconductor pattern 560 and the top surface of the hard mask 540 may be removed.

Referring to FIG. 18, an exposed portion of the tunnel insulation layer 590, the charge storage layer 580 an the first blocking layer 570 therebeneath may be removed to form a tunnel insulation layer pattern 592 and a charge storage layer pattern 582 and a first blocking layer pattern 572. In this manner, the central top surface of the semiconductor pattern 560 and the top surface of the hard mask 540 may be exposed.

In example embodiments, the tunnel insulation layer 590 and the charge storage layer 580 may be etched by a wet etch process. That is, in example embodiments, the tunnel insulation layer 590 including a silicon oxide may be etched using hydrofluoric acid as an etching solution, and the charge storage layer 580 including a silicon nitride may be etched using phosphoric acid or sulfuric acid as an etching solution. The spacer 622 including a silicon nitride may be also etched to expose the first channel 602.

In example embodiments, the first blocking layer 570 including a silicon oxide may be etched by a wet etch process using an etch solution including hydrofluoric acid. The first channel 602 may include a different material from the first blocking layer 570 and, therefore, portions of the tunnel insulation layer pattern 592, the charge storage layer pattern 582, and the first blocking layer 570 formed underneath may be protected by the first channel 602.

Referring to FIG. 19, a second channel layer may formed on the first channel 602, the exposed central top surface of the semiconductor pattern 560, and the hard mask 540.

In example embodiments, the second channel layer may be formed using substantially the same material as the first channel 602 and, as a result, the first channel 602 and the second channel layer may be merged into one layer, which may be simply referred to as a second channel layer hereinafter.

Then, after a second insulation layer filling a remaining portion of the holes 550 sufficiently may be formed on the second channel layer, the second insulation layer, the second channel layer, the tunnel insulation layer pattern 592, the charge storage layer pattern 582, the first blocking layer pattern 572, and the hard mask 340 may be planarized until a top surface of a pattern of an uppermost first insulation layer 510 may be exposed to form a second insulation layer pattern 660 filling the remaining portion of the holes 550, and the second channel layer may be transformed into a channel 642.

As a result, in example embodiments the first blocking layer pattern 572, the charge storage layer pattern 582, the tunnel insulation layer pattern 592, the channel 642, and the second insulation layer pattern 660 may be formed sequentially on the top surface of the semiconductor pattern 560 in each hole 550.

Then, an upper portion of the first structure (i.e., upper portions of the second insulation layer pattern 660, the channel 642, the tunnel insulation layer pattern 592, the charge storage layer pattern 582, and the first blocking layer pattern 572) may be removed to form a second recess 675, and a pad 670 may be formed to fill the second recess 675.

The pad 670 may be formed on each channel 642 and, thus, may form a pad array in accordance with a channel array.

The first structure, the semiconductor pattern 560 and the pad 670 in each of the holes 550 may form a second structure.

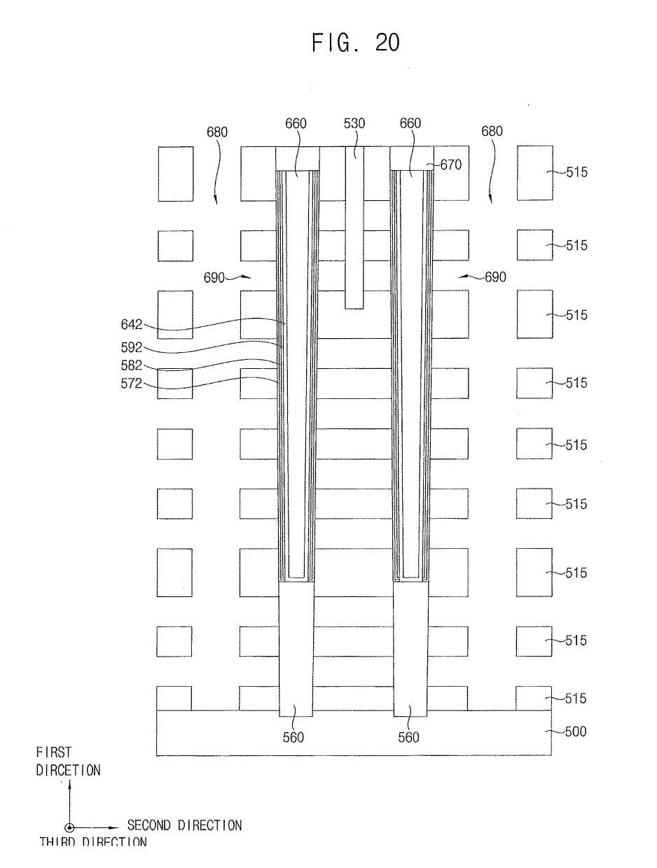

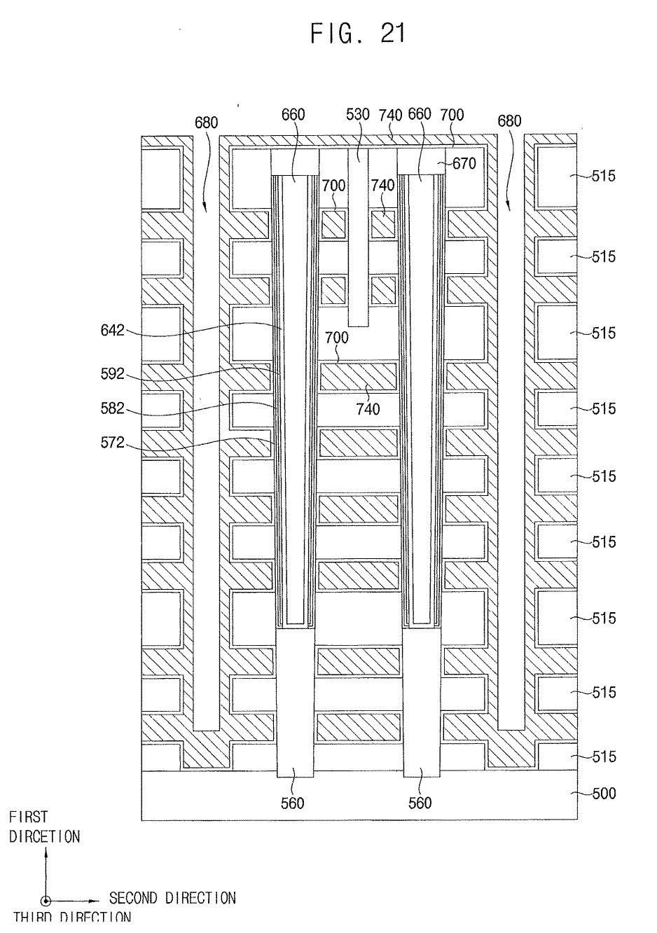

Referring to FIG. 20, a first opening 680 may be formed through the first insulation layers 510 and the sacrificial layers 520 to expose a top surface of the substrate 500.

In example embodiments, after forming a hard mask (not shown) on the uppermost first insulation layer 510, the insulation layers 510 and the sacrificial layers 520 may be, for example, dry etched using the hard mask as an etch mask to form the first opening 680. The first opening 680 may be formed to extend in the first direction.

In example embodiments, a plurality of first openings 680 may be formed in the second direction, and each first opening 680 may be extended in the third direction. The first insulation layers 510 and the sacrificial layers 520 may be transformed into first insulation layer pattern 515 and a sacrificial layer pattern, respectively. A plurality of first insulation layer patterns 515 and a plurality of sacrificial layer patterns may be formed in the second direction at each level, and each first insulation layer pattern 515 and each sacrificial layer pattern may be extended in the third direction.

Then, the sacrificial layer patterns may be removed to form a gap 690 between the first insulation layer patterns 515 at adjacent levels, and portions of an outer sidewall of the first blocking layer pattern 572 and a sidewall of the semiconductor pattern 560 may be exposed by the gap 690. In example embodiments, the sacrificial layer patterns exposed by the first opening 580 may be removed by, for example, a wet etch process using an etching solution including phosphoric acid and/or sulfuric acid.

Referring to FIGS. 21 and 22, a second blocking layer 700 may be formed on the exposed portion of the outer sidewall of the first blocking layer pattern 572, the exposed portion of the sidewall of the semiconductor pattern 560, an inner wall of the gap 690, a surface of the first insulation layer pattern 515, the exposed top surface of the substrate 500, a top surface of the pad 670, and a top surface of the division layer pattern 530, and a gate electrode layer 740 may be formed on the second blocking layer 700 to sufficiently fill remaining portions of the gap 690.

In example embodiments, the second blocking layer 700 may be formed to include, for example, a metal oxide. In example embodiments, the metal oxide may include aluminum oxide, hafnium oxide, lanthanum oxide, lanthanum aluminum oxide, lanthanum hafnium oxide, hafnium aluminum oxide, titanium oxide, tantalum oxide and/or zirconium oxide, for example.

In example embodiments, the gate electrode layer 740 may be formed to include a metal and/or a metal nitride. For example, the gate electrode layer 740 may be formed using a metal having a low electric resistance (for example, tungsten, titanium, tantalum, platinum, etc.), and a metal nitride (for example, titanium nitride, tantalum nitride, etc.).

Then, the gate electrode layer 740 may be partially removed to form gate electrodes 742, 744, and 746 in the gap 790. In example embodiments, the gate electrode layer 740 may be partially removed through a wet etch process.

In example embodiments, the gate electrodes 742, 744 and 746 may be formed to extend in the third direction, and include the GSL 746, the word line 742, and the SSL 744 sequentially formed in the first direction from the a top surface of the substrate 500. Each of the GSL 746, the word line 742 and the SSL 744 may be formed at a single level or at a plurality of levels. In example embodiments, each of the GSL 746 and the SSL 744 may be formed at 2 levels, and the word line 742 may be formed at 4 levels between the GSL 746 and the SSL 744. The GSL 746 may be formed adjacent to the semiconductor pattern 560, and the word line 742 and the SSL 744 may be formed adjacent to the channels 642 and, particularly, the SSL 744 may be formed adjacent to the division layer pattern 530.

When the gate electrode layer 740 is partially removed, portions of the second blocking layer 700 on the surface of the first insulation layer pattern 515 and on the top surfaces of the substrate 500, the pad 570, and the division layer pattern 530 may also be removed to form a second blocking layer pattern 702. The first and second blocking layer patterns 572 and 702 may define a blocking layer pattern structure 712.

In a process in which the gate electrode layer 740 and the second blocking layer 700 are partially removed, the first opening 680 exposing a top surface of the substrate 500 and being extended in the third direction may be formed again, and impurities may be implanted into the exposed top surface of the substrate 500 to form an impurity region 505. In example embodiments, the impurities may include n-type impurities (for example, phosphorus, arsenic, etc.). In example embodiments, the impurity region 505 may be formed to extend in the third direction and serve as a common source line (CSL).

A metal silicide pattern (not shown) (for example, a cobalt silicide pattern or a nickel silicide pattern) may be further formed on the impurity region 505.

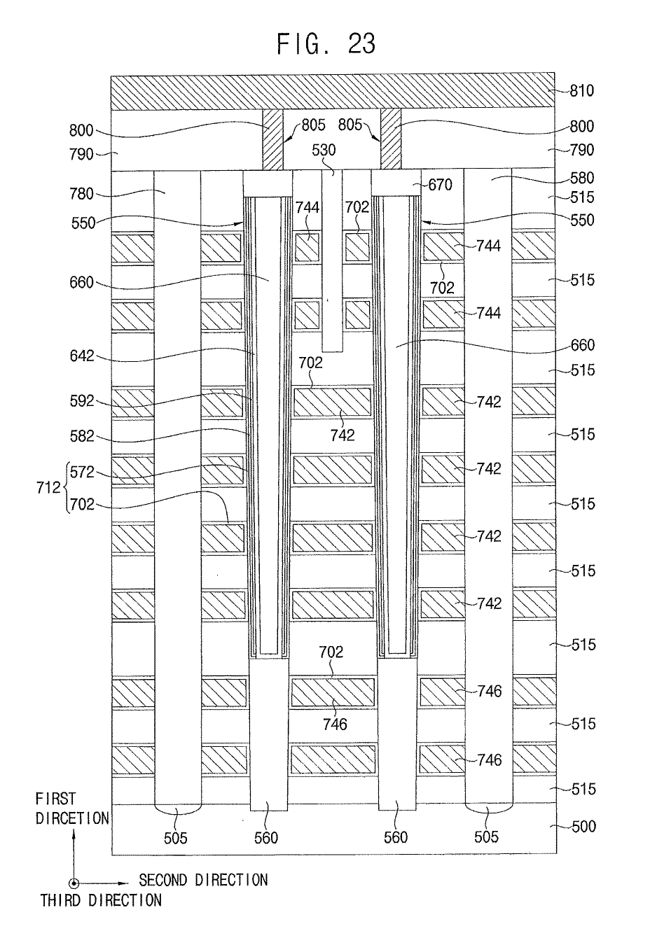

Referring to FIG. 23, a third insulation layer pattern 780 filling the first opening 680 may be formed. In example embodiments, after the third insulation layer pattern 780 filling the first opening 680 is formed on the substrate 500 and the uppermost first insulation layer pattern 515, the third insulation layer may be planarized until a top surface of the uppermost first insulation layer pattern 515 may be exposed to form a third insulation layer pattern 780.

Then, a fourth insulation layer 790 may be formed on the first and third insulation layer patterns 515 and 780, the pad 670, and the division layer pattern 530, and a second opening 805 may be formed to expose a top surface of the pad 670. In example embodiments, a plurality of second openings 805 corresponding to the pads 670 may be formed to define a second opening array.

Then, a bit line contact 800 may be formed on the pad 670 to fill the second opening 805, and a bit line 810 electrically connected to the bit line contact 800 may be formed to complete the vertical memory device. The bit line 810 and the bit line contact 800 may be formed to include, for example, a metal, a metal nitride, and/or doped polysilicon.

In example embodiments, a plurality of bit line contacts 800 corresponding to the pads 670 may be formed to define a bit line contact array, a plurality of bit lines 810 may be formed in the third direction, and each bit line 810 may be formed to extend in the second direction.

The foregoing is illustrative of example embodiments in accordance with principles of inventive concepts and is not to be construed as limiting thereof. Although a few example embodiments have been described, those skilled in the art will readily appreciate that many modifications are possible in example embodiments without materially departing from the novel teachings and advantages of the present inventive concepts. Accordingly, all such modifications are intended to be included within the scope of example embodiments as defined in the claims.

What is claimed is:

1. A wafer processing apparatus, comprising:
a reaction tube extending in a vertical direction and defining a process chamber for receiving a boat that holds a plurality of wafers; and
a gas injector configured to supply a reaction gas into the process chamber, the gas injector comprising a gas distributor extending in the vertical direction in the reaction tube, the gas distributor having a plurality of ejection holes for spraying the reaction gas,
wherein an inner diameter of the gas distributor is at least 10 mm, and a sectional area ratio of the total sectional area of the ejection holes to a sectional area of the gas distributor is about 0.3 or less.

2. The wafer processing apparatus of claim 1, wherein the inner diameter of the gas distributor is within a range of from about 10.5 mm to about 15.5 mm.

3. The wafer processing apparatus of claim 1, wherein the ratio of the height to an inner diameter of the reaction tube is about 2:1 or less.

4. The wafer processing apparatus of claim 1, wherein the diameter of the ejection hole is about 1 mm.

5. The wafer processing apparatus of claim 1, wherein the total number of the ejection holes is 20 to 40.

6. The wafer processing apparatus of claim 1, wherein the gas injector is configured to supply a silicon precursor gas through the ejection holes to perform an atomic deposition layer process on the wafers with the pressure of the reaction chamber maintained at about 50 Pa or less.

7. The wafer processing apparatus of claim 1, wherein the reaction tube comprises:
a boat receiving portion having a first radius from the center of the reaction tube and surrounding the boat;
an injector receiving portion having a second radius greater than the first radius and receiving the gas injector; and
an exhaust guide receiving portion having a third radius greater than the first radius and opposite to the injector receiving portion.

8. The wafer processing apparatus of claim 7, wherein the injector receiving portion has a first central angle at the center of the reaction tube and the exhaust guide receiving portion has a second central angle greater than the first central angle at the center of the reaction tube.

9. The wafer processing apparatus of claim 7, further comprising an exhaust guide extending in the vertical direction in the exhaust guide receiving portion and configured to collect and exhaust a gas that is ejected from the gas distributor and flows through the boat.

10. The wafer processing apparatus of claim 9, wherein the exhaust guide comprises an exhaust slit formed in an inner portion of the exhaust guide along the extending direction of the reaction tube and into which the reaction gas flows, and an exhaust hole formed in a lower outer portion of the exhaust guide and out of which the reaction gas flows.

11. The wafer processing apparatus of claim 1, wherein the gas injector further comprises a gas introduction tube connected to a lower portion of the gas distributor and configured to introduce the reaction gas into the reaction tube from a gas supply source.

12. The wafer processing apparatus of claim 1, further comprising an exhaust portion configured to exhaust gas from the reaction chamber.

13. The wafer processing apparatus of claim 1, further comprising at least one gas nozzle for supplying a reaction gas, a carrier gas, a cleaning gas or a purge gas into the reaction chamber.

14. A wafer processing apparatus, comprising:
a reaction tube extending in a vertical direction and defining a process chamber;
a boat configured to be loaded into the reaction tube and configured to hold a plurality of wafers; and
a gas injector configured to supply a reaction gas into the process chamber, the gas injector comprising a gas distributor extending in the vertical direction in the reaction tube, the gas distributor having a plurality of ejection holes for spraying the reaction gas,
wherein an inner diameter of the gas distributor is at least 10 mm, and a sectional area ratio of the total sectional area of the ejection holes to a sectional area of the gas distributor is about 0.3 or less.

15. The wafer processing apparatus of claim 14, wherein the inner diameter of the gas distributor is within a range of from about 10.5 mm to about 15.5 mm.

16. The wafer processing apparatus of claim 14, wherein the reaction tube comprises:
a boat receiving portion having a first radius from the center of the reaction tube and surrounding the boat;
an injector receiving portion having a second radius greater than the first radius and receiving the gas injector; and
an exhaust guide receiving portion having a third radius greater than the first radius and opposite to the injector receiving portion.

17. The wafer processing apparatus of claim 16, further comprising an exhaust guide extending in the vertical direction in the exhaust guide receiving portion and configured to collect and exhaust a gas that is ejected from the gas distributor and flows through the boat.

18. A batch reactor for atomic layer deposition, comprising:
a reaction tube extending in a vertical direction and defining a process chamber, the reaction tube having a ratio of height to diameter of about two-to-one or less; and
a cylindrical gas nozzle including ejection holes to spray reaction gas extending in a vertical direction in the reaction tube.

19. The batch reactor of claim 18, wherein the inner diameter of the nozzle is at least 10 mm.

20. The batch reactor of claim 18, wherein the openings of the holes consume about thirty percent or less of the total vertical area of the gas nozzle.
